(19) United States
(12) Patent Application Publication
(10) Pub. No.: US 2019/0187826 A1
(43) Pub. Date: Jun. 20, 2019

(54) TOUCH DISPLAY SUBSTRATE, MANUFACTURING METHOD THEREOF AND TOUCH DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventor: Guodong LIU, Beijing (CN)

(73) Assignees: BOE TECHNOLOGY GROUP CO., LTD., Beijing (CN); HEFEI XINSHENG OPTOELECTRONICS TECHNOLOGY CO., LTD ., Anhui (CN)

(21) Appl. No.: 15/989,227

(22) Filed: May 25, 2018

(30) Foreign Application Priority Data
Dec. 14, 2017 (CN) 201711338273.7

(51) Int. Cl. G06F 3/042; H01L 27/32; H01L 51/52; H01L 51/56; G09G 3/3275

(52) U.S. Cl. CPC G06F 3/042; H01L 27/3244; H01L 27/323; H01L 51/5246; G06F 3/0488; G09G 3/3275; H01L 2227/323; G09G 2310/0297; H01L 51/56

(57) ABSTRACT

The present disclosure provides a touch display substrate, a manufacturing method and a touch display device. The touch display substrate includes a transparent base substrate, and a touch electrode layer, a TFT functional layer and an OLED layer arranged on the base substrate. The OLED layer is capable of emitting light toward the base substrate, and the touch electrode layer is arranged between the base substrate and the OLED layer.

### CROSS-REFERENCE TO RELATED APPLICATION

This application claims priority to Chinese Patent Application No. 201711338273.7 filed on Dec. 14, 2017, which is incorporated herein by reference in its entirety.

### TECHNICAL FIELD

The present disclosure relates to the field of display technology, in particular to a touch display substrate, a manufacturing method thereof and a touch display device.

### BACKGROUND

Along with the rising of the information society and the development of the science and technology, more and more display technologies have been proposed, e.g., a conventional liquid crystal display technology, an organic light-emitting diode (OLED) display technology, and an electrophoretic display technology. As compared with the other display devices, an OLED display device has such advantages as self-luminescence, rapid response, high brightness value and wide viewing angle. In addition, for the OLED display technology, it is unnecessary to form a liquid crystal layer, so it is able to provide a flexible display device which may be curled, folded or even worn by a user. Therefore, the flexible display device is a good portable product.

An OLED touch display device is provided with a touch function, and a touch operation may be made by a finger or stylus intuitively and conveniently, so the OLED touch display device has been widely used in smart terminals and wearable devices. As compared with an on-cell OLED touch display device, an in-cell OLED touch display device has such advantages as being light and thin as well as low manufacture cost, so it has attracted more and more attentions.

For a conventional in-cell OLED touch display device, usually a touch electrode layer is formed on a package plate of an OLED element. There is a too large distance between the touch electrode layer and a touch display surface of the OLED touch display device, so touch sensitivity may be adversely affected. In addition, a display signal transmission layer is arranged between a touch signal transmission layer and the finger, so interference may easily occur.

### SUMMARY

In one aspect, the present disclosure provides in some embodiments a touch display substrate, including a transparent base substrate, and a touch electrode layer, a thin film transistor (TFT) functional layer and an OLED layer arranged on the base substrate. The OLED layer is configured to emit light toward the base substrate, and the touch electrode layer is arranged between the base substrate and the OLED layer.

In a possible embodiment of the present disclosure, the OLED layer includes an anode layer, a cathode layer and an organic layer arranged between the anode layer and the cathode layer. The anode layer is arranged at a side of the touch electrode layer away from the base substrate, the touch electrode layer is arranged between the anode layer and the TFT functional layer, and the cathode layer is arranged at a side of the anode layer away from the touch electrode layer.

In a possible embodiment of the present disclosure, the anode layer is a transparent electrode layer and is multiplexed as a common electrode, the cathode layer includes a plurality of cathodes arranged in an array form, and each of the cathodes is electrically connected to a drain electrode of a TFT at the TFT functional layer and is multiplexed as a pixel electrode.

In a possible embodiment of the present disclosure, the TFT functional layer, the touch electrode layer and the OLED layer are stacked sequentially on the base substrate.

In a possible embodiment of the present disclosure, the touch electrode layer, the TFT functional layer and the OLED layer are stacked sequentially on the base substrate.

In a possible embodiment of the present disclosure, the organic layer includes a light-emitting layer configured to emit light beams in three-primary colors.

In a possible embodiment of the present disclosure, the touch display substrate further includes a cover plate arranged opposite to the base substrate and a sealant frame arranged between the base substrate and the cover plate. A sealed cavity is defined by the base substrate, the cover plate and the sealant frame, and the TFT functional layer, the touch electrode layer and the OLED layer are inside the sealed cavity.

In another aspect, the present disclosure provides in some embodiments a touch display device including the above-mentioned touch display substrate.

In a possible embodiment of the present disclosure, the touch display substrate further includes a cover plate arranged opposite to a base substrate and a sealant frame arranged between the base substrate and the cover plate. A sealed cavity is defined by the base substrate, the cover plate and the sealant frame, and a TFT functional layer, a touch electrode layer and an OLED layer are inside the sealed cavity.

In a possible embodiment of the present disclosure, the touch display device further includes a circuit board arranged on the base substrate, the OLED layer and the TFT functional layer each is electrically connected to a first connection region of the circuit board, and the touch electrode layer is electrically connected to a second connection region of the circuit board different from the first connection region.

In a possible embodiment of the present disclosure, the sealant frame is attached onto a middle portion of the circuit board in such a manner that a part of the circuit board is inside the sealed cavity and another part of the circuit board extends beyond the sealed cavity and is connected to a driving unit. The touch electrode layer, the TFT functional layer and the OLED layer each is electrically connected to the circuit board.

In a possible embodiment of the present disclosure, the first connection region and the second connection region are arranged at two opposite sides of the circuit board respectively.

In a possible embodiment of the present disclosure, an insulation layer is arranged at a side of the touch electrode layer away from the base substrate and provided with a hollowed-out structure at a position adjacent to the circuit board, and a pin of the touch electrode layer extends through the hollowed-out structure and is connected to the second connection region of the circuit board.

In yet another aspect, the present disclosure provides in some embodiments a method for manufacturing a touch display substrate, including: providing a transparent base substrate; and forming a touch electrode layer, a TFT functional layer and an OLED layer on the base substrate, the OLED layer being configured to emit light toward the base substrate, the touch electrode layer being arranged between the base substrate and the OLED layer.

In a possible embodiment of the present disclosure, the method further includes sealing the touch electrode layer, the TFT functional layer and the OLED layer though a cover plate and a sealant frame in such a manner that the touch electrode layer, the TFT functional layer and the OLED layer are inside a sealed cavity defined by the base substrate, the cover plate and the sealant frame.

### BRIEF DESCRIPTION OF THE DRAWINGS

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a perspective view of a touch display device according to some embodiments of the present disclosure;

FIG. 2 is a sectional view of a touch display substrate of the touch display device taken along line A in FIG. 1;

FIG. 3 is a plan view of the touch display substrate of the touch display device according to some embodiments of the present disclosure;

FIG. 4 is an enlarged view of a portion IV in FIG. 2;

FIG. 5 is a flow chart of a method for manufacturing the touch display substrate according to some embodiments of the present disclosure; and

FIGS. 6 and 7 are schematic views showing the touch display substrate during manufacturing according to some embodiments of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

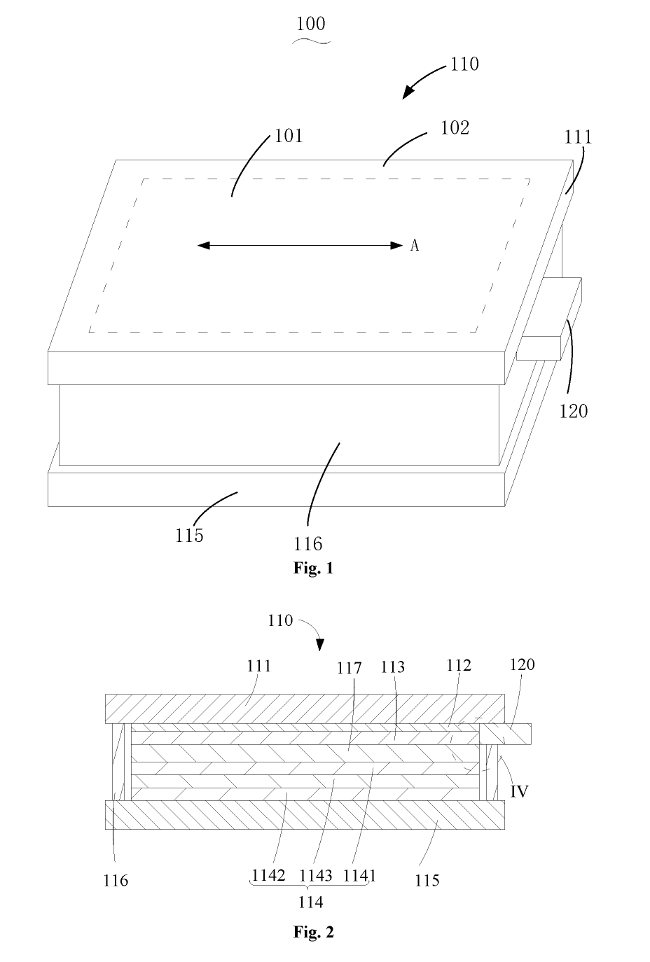

The present disclosure provides in some embodiments a touch display device 100 as shown in FIG. 1 which is a perspective view of the touch display device and FIG. 2 which is a sectional view of a touch display substrate taken along line A. The touch display device 100 includes a display region 101 and a peripheral region 102 surrounding the display region 101. The display region 101 is mainly used to achieve a touch display function of the touch display device 100, and the peripheral region 102 is mainly used for the formation of lines thereon.

The touch display device 100 includes a touch display substrate 110. The touch display substrate 100 includes a base substrate 111, a TFT functional layer 112, a touch electrode layer 113, an OLED layer 114 and a cover plate 115 superimposed one on another. In addition, the touch display substrate 110 further includes a sealant frame 116 arranged at a side of the touch display substrate 110. The base substrate 111 is a transparent substrate. A sealed cavity is formed by the base substrate 111, the cover plate 115 and the sealant frame 116, and the TFT functional layer 112, the touch electrode 113 and the OLED layer 114 are arranged inside the sealed cavity.

The TFT functional layer 112 is arranged between the base substrate 111 and the OLED layer 114, and the touch electrode 113 is arranged between the base substrate 111 and the OLED layer 114. To be specific, the touch electrode layer 113 is arranged between the TFT functional layer 112 and the OLED layer 114.

The OLED 114 is capable of emitting light toward the base substrate 111, and a surface of the base substrate 111 away from the OLED layer 114 serves as a touch display surface of the touch display device 100.

According to the touch display device in the embodiments of the present disclosure, the touch electrode layer 113 is arranged closer to the base substrate 111 than the OLED layer 114, so the touch electrode layer 113 is arranged closer to the touch display surface of the touch display device 100. As a result, it is able to reduce a distance between the touch electrode layer 113 and the touch display surface of the touch display device 100, thereby improving the touch sensitivity of the touch display device 100. In such a manner, during a touch display operation, a touch signal on the touch electrode layer 113 is between the a finger and a display signal on the OLED layer 114, so it is able to prevent the display signal from interfering with the touch signal during the touch display operation, thereby further improving the touch sensitivity.

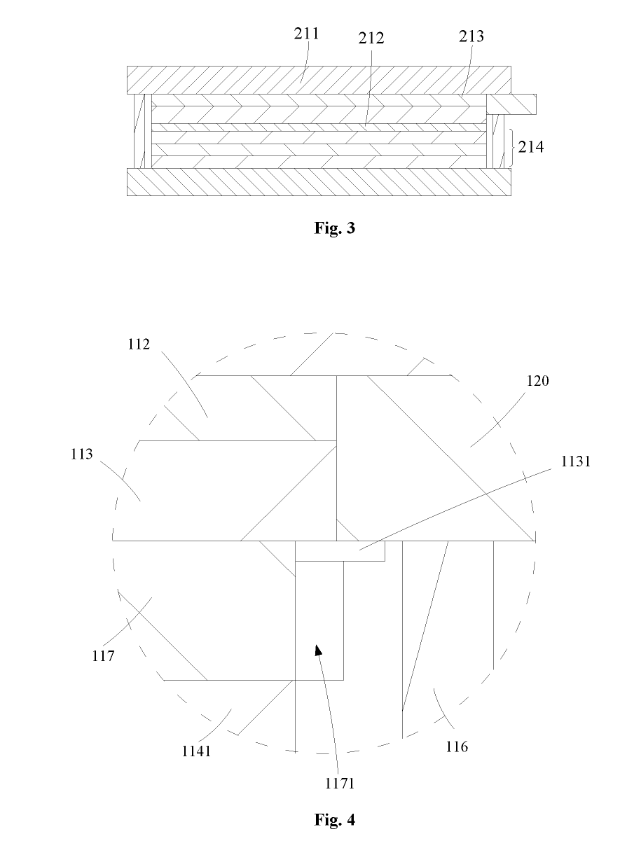

The above description is given in the case that the TFT functional layer 112 is arranged between the base substrate 111 and the touch electrode layer 113. However as shown in FIG. 3 which is a plan view of the touch display substrate, a TFT functional layer 212 is arranged between an OLED layer 214 and a touch electrode 213, and the touch electrode layer 213 is arranged between the TFT functional layer 212 and a base substrate 211.

The touch electrode layer may be of a single-layered or double-layered ITO (indium tin oxide) structure, or a metal mesh structure, which will not be particularly defined herein.

As shown in FIG. 1, the OLED layer 114 includes an anode layer 1141, a cathode layer 1142 and an organic layer 1143 arranged between the anode layer 1141 and the cathode layer 1142. The anode layer 1141 is arranged at a side of the touch electrode layer 113 away from the base substrate 111, the touch electrode layer 113 is arranged between the TFT functional layer 112 and the anode layer 1141, and the cathode layer 1142 is arranged at a side of the anode layer 1141 away from the touch electrode layer 113.

In a possible embodiment of the present disclosure, the anode layer 1141 is formed into a single block, and it may be multiplexed as a common electrode of the touch display device 100.

In a possible embodiment of the present disclosure, the cathode layer 1142 includes a plurality of cathodes (not shown) arranged independent of each other and in an array form. Each cathode may be electrically connected to a drain electrode of a TFT at the TFT functional layer 112 through via-holes in the organic layer 1143, the anode layer 1141 and the touch electrode layer 113. Under the control of the TFT, each cathode may be multiplexed as a pixel electrode of the touch display device 100.

Here, the anode layer 1141 adjacent to the touch electrode layer 113 is formed into a single block and multiplexed as the common electrode, while the cathode layer 1142 away from the touch electrode layer 113 is formed into a plurality of blocks and multiplexed as the pixel electrodes, so a touch electrode may be arranged far away from the pixel electrode. As compared with a situation where the anode layer is formed into a plurality of blocks, it is able to reduce a magnitude of a voltage fluctuation in the case that signal interference occurs for the common electrode and prevent the common electrode from interfering with the touch electrode layer, thereby to reduce the possibility and the degree of the mutual interference between a signal in the anode layer and a signal in the touch electrode layer.

The organic layer 1143 further includes a light-emitting layer (not shown) for emitting light beams in three primary colors, so as to provide the touch display device 100 with a red (R)/green (G)/blue (B) light-emission mode. In addition, the organic layer 1143 may further include one or more of an electron injection layer, an electron transport layer, a hole injection layer and a hole transport layer.

The touch display device 100 further includes a circuit board 120 arranged on the base substrate 111. The sealant frame 116 is attached onto a middle portion of the circuit board 120 in such a manner that a part of the circuit board 120 extends beyond the sealed cavity to be connected to an element such as a driving integrated circuit (IC) while another part of the circuit board 120 is inside the sealed cavity defined by the base substrate 111, the cover plate 115 and the sealant frame 116. The touch electrode layer 113, the TFT functional layer 112 and the OLED layer 114 are each electrically connected to the circuit board 120.

At the peripheral region 102 of the touch display device 100, the OLED layer 114 and the TFT functional layer 112 are connected to a first connection region of the circuit board 120. To be specific, the anode layer 1141 of the OLED layer 114 is connected to the first connection region of the circuit board 120, and the cathode 1142 is connected to the first connection region of the circuit board 120 through the OLED functional layer 112. The touch electrode layer 113 is connected, through an electrode pin of the touch electrode layer 113, to a second connection region of the circuit board 120 different from the first connection region.

The first connection region and the second connection region may be arranged at two opposite sides of the circuit board 120 respectively. Of course, they may also be arranged at a same side of the circuit board 120.

Through the connection of the OLED layer and the TFT functional layer to the first connection region of the circuit board and the connection of the touch electrode layer to the second connection region of the circuit board, a display signal and a touch signal may be provided in a separate manner, and a display operation and a touch operation may be performed simultaneously without any necessary to drive the touch display device in a time-division manner. As a result, it is able to use a conventional driving circuit without any necessary to provide an additional circuit, thereby to simplify the design.

As shown in FIG. 4 which is an enlarged view of a portion IV in FIG. 2, the touch display substrate 110 further includes an insulation layer 117 arranged at a side of the touch electrode layer 113 away from the base substrate 111. To be specific, the insulation layer 117 is arranged between the touch electrode layer 113 and the anode layer 1141. The insulation layer 117 is provided with a hollowed-out structure 1171 at a position adjacent to the circuit board 120, so that a pin 1131 of the touch electrode layer 113 is capable of extending through the hollowed-out structure 1171 and being connected to the second connection region of the circuit board 120.

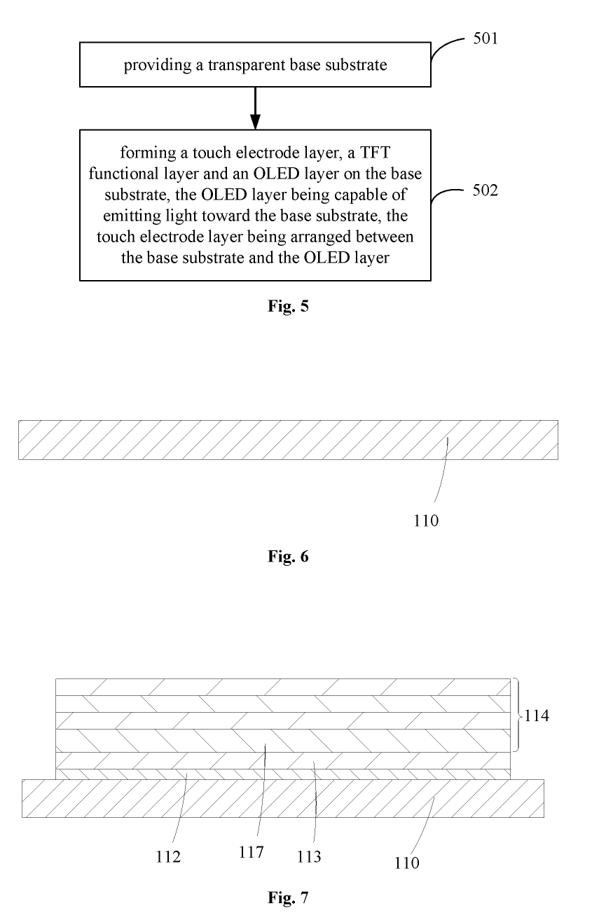

As shown in FIG. 5, the present disclosure further provides in some embodiments a method for manufacturing the touch display substrate 110 in FIG. 2, which includes the following steps 501 and 502.

Step 501: providing a transparent base substrate. To be specific, the transparent base substrate 111 may be provided, and one surface of the base substrate 111 may be a touch display surface, as shown in FIG. 6.

Step 502: forming a touch electrode layer, a TFT functional layer and an OLED layer on the base substrate, the OLED layer being capable of emitting light toward the base substrate, the touch electrode layer being arranged between the base substrate and the OLED layer. To be specific, the TFT functional layer 112, the touch electrode layer 113 and the OLED layer 114 may be formed on the base substrate 111, and the touch electrode layer 113 may be arranged between the base substrate 111 and the OLED layer 114, as shown in FIG. 7. Further, the TFT functional layer 112 may be arranged between the base substrate 111 and the touch electrode layer 113, and the touch electrode layer 113 may be arranged between the TFT functional layer 112 and the OLED layer 114.

The OLED layer 114 is capable of emitting light toward the base substrate 111, and a surface of the base substrate 111 away from the OLED layer 114 serves as the touch display surface of the touch display device 100.

After the formation of the touch electrode layer 113, the insulation layer 117 may be further formed on the touch electrode layer 113, so as to enable the touch electrode layer 113 to be insulated from the OLED layer 114.

After the formation of the above layers, these layers may be placed within a sealed cavity defined by the base substrate 111, a cover plate and a sealant frame, so as to acquire the touch display substrate in FIG. 2.

According to the touch display substrate, the manufacturing method thereof and the touch display device in the embodiments of the present disclosure, the touch display substrate includes the transparent base substrate, and the touch electrode layer, the TFT functional layer and the OLED layer arranged on the base substrate. The OLED layer is capable of emitting light toward the base substrate, and the touch electrode layer is arranged between the base substrate and the OLED layer. In this way, the touch electrode layer is arranged closer to the touch display surface of the touch display device, so as to reduce a distance between the touch electrode layer and the touch display surface of the touch display device, thereby to improve the touch sensitivity of the touch display device. In addition, the touch signal transmission layer is arranged between the finger and the display signal transmission layer, so it is able to prevent the display signal from interfering with the touch signal during the touch display operation, thereby to further improve the touch sensitivity.

The above are merely optional embodiments of the present disclosure, but the present disclosure is not limited thereto. Obviously, a person skilled in the art may make further modifications and improvements without departing from the spirit of the present disclosure, and these modifications and improvements shall also fall within the scope of the present disclosure.

What is claimed is:

1. A touch display substrate, comprising a transparent base substrate, and a touch electrode layer, a thin film transistor (TFT) functional layer and an organic light-emitting diode (OLED) layer arranged on the base substrate, wherein the OLED layer is configured to emit light toward the base substrate, and the touch electrode layer is arranged between the base substrate and the OLED layer.

2. The touch display substrate according to claim 1, wherein the OLED layer comprises an anode layer, a cathode layer and an organic layer arranged between the anode layer and the cathode layer, the anode layer is arranged at a side of the touch electrode layer away from the base substrate, the touch electrode layer is arranged between the anode layer and the TFT functional layer, and the cathode layer is arranged at a side of the anode layer away from the touch electrode layer.

3. The touch display substrate according to claim 2, wherein the anode layer is a transparent electrode layer and is multiplexed as a common electrode, the cathode layer comprises a plurality of cathodes arranged in an array form, and each of the cathodes is electrically connected to a drain electrode of a TFT at the TFT functional layer and is multiplexed as a pixel electrode.

4. The touch display substrate according to claim 1, wherein the TFT functional layer, the touch electrode layer and the OLED layer are stacked sequentially on the base substrate.

5. The touch display substrate according to claim 1, wherein the TFT functional layer, the touch electrode layer and the OLED layer are stacked sequentially on the base substrate.

6. The touch display substrate according to claim 2, wherein the organic layer comprises a light-emitting layer configured to emit light beams in three-primary colors.

7. The touch display substrate according to claim 1, further comprising a cover plate arranged opposite to the base substrate and a sealant frame arranged between the base substrate and the cover plate, wherein a sealed cavity is defined by the base substrate, the cover plate and the sealant frame, and the TFT functional layer, the touch electrode layer and the OLED layer are inside the sealed cavity.

8. A touch display device, comprising a touch display substrate, wherein the touch display substrate comprises a transparent base substrate, and a touch electrode layer, a thin film transistor (TFT) functional layer and an organic light-emitting diode (OLED) layer arranged on the base substrate, wherein the OLED layer is configured to emit light toward the base substrate, and the touch electrode layer is arranged between the base substrate and the OLED layer.

9. The touch display device according to claim 8, wherein the OLED layer comprises an anode layer, a cathode layer and an organic layer arranged between the anode layer and the cathode layer, the anode layer is arranged at a side of the touch electrode layer away from the base substrate, the touch electrode layer is arranged between the anode layer and the TFT functional layer, and the cathode layer is arranged at a side of the anode layer away from the touch electrode layer.

10. The touch display device according to claim 9, wherein the anode layer is a transparent electrode layer and is multiplexed as a common electrode, the cathode layer comprises a plurality of cathodes arranged in an array form, and each of the cathodes is electrically connected to a drain electrode of a TFT at the TFT functional layer and is multiplexed as a pixel electrode.

11. The touch display device according to claim 8, wherein the touch display substrate further comprises a cover plate arranged opposite to the base substrate and a sealant frame arranged between the base substrate and the cover plate, wherein a sealed cavity is defined by the base substrate, the cover plate and the sealant frame, and the TFT functional layer, the touch electrode layer and the OLED layer are in the sealed cavity.

12. The touch display device according to claim 8, further comprising a circuit board arranged on the base substrate, wherein the OLED layer and the TFT functional layer each is electrically connected to a first connection region of the circuit board, and the touch electrode layer is electrically connected to a second connection region of the circuit board different from the first connection region.

13. The touch display device according to claim 8, wherein the sealant frame is attached onto a middle portion of the circuit board in such a manner that a part of the circuit board is inside the sealed cavity and another part of the circuit board extends beyond the sealed cavity and is connected to a driving unit, and the touch electrode layer, the TFT functional layer and the OLED layer each is electrically connected to the circuit board.

14. The touch display device according to claim 12, wherein the first connection region and the second connection region are arranged at two opposite sides of the circuit board respectively.

15. The touch display device according to claim 12, wherein an insulation layer is arranged at a side of the touch electrode layer away from the base substrate and provided with a hollowed-out structure at a position adjacent to the circuit board, and a pin of the touch electrode layer extends through the hollowed-out structure and is connected to the second connection region of the circuit board.

16. A method for manufacturing a touch display substrate, comprising:
providing a transparent base substrate; and
forming a touch electrode layer, a thin film transistor (TFT) functional layer and an organic light-emitting diode (OLED) layer on the base substrate, wherein the OLED layer is configured to emit light toward the base substrate, and the touch electrode layer is arranged between the base substrate and the OLED layer.

17. The method according to claim 16, further comprising sealing the touch electrode layer, the TFT functional layer and the OLED layer though a cover plate and a sealant frame in such a manner that the touch electrode layer, the TFT functional layer and the OLED layer are inside a sealed cavity defined by the base substrate, the cover plate and the sealant frame.
